(19) United States
(12) Patent Application Publication
(10) Pub. No.: US 2005/0116309 A1
(43) Pub. Date: Jun. 2, 2005

(54) Semiconductor light-emitting element, manufacturing method therefor and semiconductor device

(76) Inventors: Shouichi Ohyama, Souraku-gun (JP); Tetsurou Murakamii, Tenri-shi (JP); Takahisa Kurahashi, Kashiba-shi (JP); Osamu Yamamoto, Nara-shi (JP); Hiroshi Nakatsu, Mihara-shi (JP)

Correspondence Address: NIXON & VANDERHYE, PC, 1100 N GLEBE ROAD, 8TH FLOOR, ARLINGTON, VA, 22201-4714, US

(21) Appl. No.: 10/971,688

(22) Filed: Oct. 25, 2004

(30) Foreign Application Priority Data
Oct. 30, 2003 (JP) 2003-369996
Aug. 17, 2004 (JP) 2004-237525

(51) Int. Cl. H01L 27/14

(52) U.S. Cl. 257/431; 257/461

(57) ABSTRACT

A semiconductor light-emitting element has a semiconductor laminate including an active layer emitting light of a prescribed emission wavelength and a step located at an in-depth position beyond the active layer. The element also has a substrate transparent to the emission wavelength, a first electrode provided on a surface of the semiconductor laminate, and a second electrode provided on the step. The substrate transparent to the emission wavelength improves the external emission efficiency. The locations of the first and second electrodes substantially prevent current to flow through a direct connection interface between the semiconductor laminate and the substrate. Thereby, the element exhibits satisfactory electrical characteristics even when an incomplete junction attributed to hillock or the like is generated in the direct connection interface.

### CROSS-REFERENCE TO RELATED APPLICATIONS

This nonprovisional application claims priority under 35 U.S.C. §119(a) on Patent Application No. 2003-369996 filed in Japan on 03 Oct. 2003 and 2004-237525 filed in Japan on 17 Aug. 2004, the entire contents of which are incorporated herein by reference.

### BACKGROUND OF THE INVENTION

The present invention relates to a semiconductor light-emitting element provided with a substrate transparent to its emission wavelength and a manufacturing method therefor. The semiconductor light-emitting element of this kind is suitably used as a constituent of optical transmission, display, an auxiliary light source of a CCD (charge coupled device) camera, a back light of an LCD (liquid crystal display) or the like.

This invention relates also to a semiconductor device provided with such the semiconductor light-emitting element. In recent years, light-emitting diodes (LED's) among the semiconductor light-emitting elements have been widely used for optical communications, an LED information display panel and so on. It is important that these light-emitting diodes have high luminance. The luminance, i.e., the external quantum efficiency of a light-emitting diode is determined by the internal quantum efficiency and the external emission efficiency. Among these, the external emission efficiency is greatly influenced by the element structure because the external emission efficiency is efficiency of taking light generated in the light-emitting layer from the element.

To improve the external emission efficiency, a substrate transparent to the emission wavelength is employed in the light-emitting diode. This is because light can be produced not only from the upper surface but also from four side surfaces in the case of employing a substrate transparent to the emission wavelength, while only the emission light to the upper surface can be produced in the case of employing a substrate opaque to the emission wavelength. Moreover, it becomes possible to emit the reflected light on the lower surface also from the upper surface and the side surfaces. This method is applied to an infrared light-emitting diode that uses an InGaAsP based semiconductor material, red and infrared light-emitting diodes that use an AlGaAs based semiconductor material, a yellow light-emitting diode that uses a GaAsP based semiconductor material, a green light-emitting diode that uses a GaP based semiconductor material and so on.

As a manufacturing method for fabricating an AlGaInP based light-emitting diode provided with a substrate transparent to the emission wavelength, there is known a method as shown in FIGS. 5A through 5D (refer to, for example, JP 3230638A). That is, as shown in FIG. 5A, an n-type semiconductor layer 103, an AlGaInP based active layer 104 and a p-type semiconductor layer (including a GaP layer (not shown)) 105 are first epitaxially grown on an n-type GaAs substrate 101 opaque to the emission wavelength. Next, the surface of the p-type semiconductor layer 105 is polishing into a mirror finished surface, and thereafter, a p-type GaP substrate 110 transparent to the emission wavelength is put in contact with this surface to carry out heat treatment. Thereby, the p-type GaP substrate 110 is directly connected to the surface of the p-type semiconductor layer 105 as shown in FIG. 5B. Subsequently, the n-type GaAs substrate 101 is removed as shown in FIG. 5C, and thereafter, electrodes 111 and 112 are formed at the top and bottom, respectively, as shown in FIG. 5D. According to this method, since the GaAs substrate 101 is removed after direct connection of the GaP substrate 110, the wafer is not put into a thin state constructed of only the epitaxial growth layers 103, 104 and 105 during the process. Wafer cracking can therefore be prevented.

In this kind of semiconductor light-emitting element, as the result of lattice mismatching of the active layer 104 with the p-type semiconductor layer 105, the surface does not only become a complete mirror finished surface during the epitaxial growth process, but also hillock may be generated which is a protruding crystal defect. Once the hillock is generated, the surface of the p-type semiconductor layer 105 is not completely flattened no matter how much the surface is polished. Thus the peripheral portion of the hillock is not directly connected to cause an incomplete junction. For the above reasons, a current does not uniformly spread within the direct connection interface when electricity is turned on between the electrodes 111 and 112 after the element is completed. This leads to a rise in the forward voltage V_{F} and yield reduction, disadvantageously.

### SUMMARY OF THE INVENTION

An object of the present invention is therefore to provide a semiconductor light-emitting element and a manufacturing method thereof, which are capable of exhibiting satisfactory electrical characteristics even when an incomplete junction attributed to hillock or the like is generated at the direct connection interface between a semiconductor laminate including an active layer and a substrate transparent to the emission wavelength, and consequently obtaining a high yield.

Moreover, another object of this invention is to provide a semiconductor device provided with such the semiconductor light-emitting element.

In order to achieve the aforementioned objects, this present invention provides a semiconductor light-emitting element comprising:
a semiconductor laminate including an active layer that emits light of a prescribed emission wavelength; and
a substrate that is transparent to the emission wavelength and directly connected to the semiconductor laminate, wherein
a step is formed in the semiconductor laminate, the step being located at an in-depth position beyond the active layer from a surface of the semiconductor laminate opposite to a direct connection interface between the semiconductor laminate and the substrate, and
a first electrode and a second electrode are provided on the surface and the step of the semiconductor laminate, respectively.

According to the semiconductor light-emitting element of this invention, an electric power is applied across the first electrode and the second electrode during operation, that is, electrification is conducted between the surface and the step of the semiconductor laminate through the active layer included in the semiconductor laminate so that the active layer emits light of the prescribed emission wavelength. This semiconductor light-emitting element is provided with the substrate transparent to the emission wavelength. Therefore, light can be produced not only from the upper surface but also from the four side surfaces, and also the reflected light on the lower surface can be emitted from the upper surface and the side surfaces. Therefore, the external emission efficiency can be improved. Furthermore, the electrification is conducted between the surface and the step of the semiconductor laminate, and therefore, current does not substantially flow through the direct connection interface located between the semiconductor laminate and the substrate. Therefore, the state of the direct connection interface scarcely has influence on the electrical characteristics. Therefore, even when an incomplete junction attributed to the hillock or the like is generated in the direct connection interface, satisfactory electrical characteristics can be exhibited, and thus a high yield can be obtained.

As a material for the active layer, there can be enumerated, for example, an AlGaInP based semiconductor. The AlGaInP based semiconductor means a semiconductor of which the compositional formula is expressed as (Al_{y}Ga_{1-y})_{z}In_{1-z}P (0≦y≦1, 0<z<1).

GaP, for example, is enumerated as a material for the substrate.

Moreover, it is desirable that, for example, an n-type semiconductor layer, the active layer and a p-type semiconductor layer are laminated in this order from the side of the substrate so that the semiconductor laminate forms a light-emitting diode.

In the semiconductor light-emitting element of one embodiment,
the first electrode has a translucent electrode layer that is transparent to the emission wavelength and provided entirely on the surface of the semiconductor laminate, excluding the step.

In the semiconductor light-emitting element of this one embodiment, the translucent electrode layer owned by the first electrode is transparent to the emission wavelength, and therefore, the light emission to the upper surface of the chip is not disturbed by the translucent electrode layer. Therefore, the external emission efficiency can further be improved. Moreover, electrification current is diffused by this translucent electrode layer during operation, and thus a current is uniformly injected into the active layer. Therefore, the internal quantum efficiency is improved. Consequently, the characteristics of the semiconductor light-emitting element are improved, and high luminance is achieved.

In the semiconductor light-emitting element of one embodiment,
the semiconductor laminate and the substrate are electrically separated from each other by a constituent that constitutes a p-n junction.

The expression “electrical separation” means that layers provided with interposition of a p-n junction is electrically made nonconductive by a depletion layer caused by the p-n junction. If the p-n junction is reversely biased, the depletion layer caused by the p-n junction spreads to allow electrical separation to be secured.

In the semiconductor light-emitting element of this one embodiment, the semiconductor laminate and the substrate are electrically separated from each other by the constituent that constitutes the p-n junction, and therefore, the electrical characteristics become less susceptible to the state of the direct connection interface.

In the semiconductor light-emitting element of one embodiment,
the constituent that constitutes the p-n junction is comprised of the n-type substrate and a p-type semiconductor layer deposited on the substrate.

In the semiconductor light-emitting element of this one embodiment, the constituent that constitutes the p-n junction is simply constructed, for example, by preparatorily depositing a p-type semiconductor layer on an n-type substrate and by directly connecting the surface located on the p-type semiconductor layer side of the substrate to the semiconductor laminate.

For example, GaP can be enumerated as a material for the substrate. Also, for example, p-type (Al_{y}Ga_{1-y})_{z}In_{1-z}P (0≦y≦1, 0<z<1) can be enumerated as a material for the p-type semiconductor layer.

In the semiconductor light-emitting element of one embodiment,
the constituent that constitutes the p-n junction is comprised of the n-type substrate and a p-type diffusion layer formed by impurity diffusion on a surface of the substrate.

In the semiconductor light-emitting element of this one embodiment, the constituent that constitutes the p-n junction is simply constructed, for example, by preparatorily forming a p-type semiconductor layer on the surface of the n-type substrate with use of impurity diffusion and by directly connecting the surface located on the p-type semiconductor layer side of the substrate to the semiconductor laminate.

In the semiconductor light-emitting element of one embodiment,
a thickness between the step of the semiconductor laminate and the direct connection interface is not smaller than 1 μm and not greater than 4 μm.

In the semiconductor light-emitting element of this one embodiment, the thickness between the step of the semiconductor laminate and the direct connection interface to the substrate is not greater than 4 μm. Therefore, the step can be stably set to the in-depth position beyond the active layer by carrying out etching from the surface of the semiconductor laminate. Moreover, the thickness between the step of the semiconductor laminate and the direct connection interface to the substrate is not smaller than 1 μm. Therefore, the electric conduction is stably secured between the semiconductor laminate and the second electrode on the step.

In the semiconductor light-emitting element of one embodiment,
the semiconductor laminate includes a current diffusion layer that is located between the active layer and the first electrode and has the surface of the semiconductor laminate.

In the semiconductor light-emitting element of one embodiment,
the current diffusion layer is comprised of (Al_{y}Ga_{1-y})_{z}In_{1-z}P(0≦y≦1, 0≦z≦1)

In the semiconductor light-emitting element of one embodiment,
a thickness of the current diffusion layer is not smaller than 0.2 μm and not greater than 10 μm.

This invention provides a semiconductor device having a semiconductor light-emitting element comprising:
a semiconductor laminate including an active layer that emits light of a prescribed emission wavelength; and
a substrate that is transparent to the emission wavelength and directly connected to the semiconductor laminate, wherein
a step is formed in the semiconductor laminate, the step being located at an in-depth position beyond the active layer from a surface of the semiconductor laminate opposite to a direct connection interface between the semiconductor laminate and the substrate,
a first electrode and a second electrode are provided on the surface and the step of the semiconductor laminate, respectively, and
a surface of the substrate surface located opposite to the direct connection interface is bonded to an electrically insulating heat sink.

In this semiconductor device having the semiconductor light-emitting element, the heat sink does not become any electrification path for the semiconductor light-emitting element, so that the heat sink is only required to have the functions of heat radiation and mounting. This allows variation of adoptable packages to be widened. That is, according to the present invention, the electrically insulating heat sink can be used in the semiconductor device.

In the semiconductor device of one embodiment,
the electrically insulating heat sink is made of aluminum nitride.

The thermal conductivity of the heat sink is comparatively higher than other kind of insulating material since the heat sink is made of aluminum nitride (AlN). Therefore, and thus, the temperature characteristic of the semiconductor is improved.

The present invention provides a semiconductor light-emitting element manufacturing method comprising:
growing a semiconductor laminate including an active layer that emits light of a prescribed emission wavelength on a first semiconductor substrate;
directly connecting a second semiconductor substrate transparent to the emission wavelength of the active layer to a surface of the semiconductor laminate opposite to another surface of the semiconductor laminate contacting the first semiconductor substrate;
removing the first semiconductor substrate;
   forming a step in the semiconductor laminate by etching, the step being located at an in-depth position beyond the active layer from a surface of the semiconductor laminate opposite to a direct connection interface between the semiconductor laminate and the second substrate; and
providing a first electrode and a second electrode on the surface and the step of the semiconductor laminate, respectively.

According to the manufacturing method of this invention, the above-mentioned semiconductor light-emitting element of the aforementioned invention is easily manufactured.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a view showing an in-process semiconductor light-emitting element in a manufacturing process according to an embodiment of the present invention;

FIG. 2 is a view showing an in-process semiconductor light-emitting element in the manufacturing process according to the embodiment;

FIG. 3 is a view showing an in-process semiconductor light-emitting element in the manufacturing process according to the embodiment;

FIG. 4 is a view showing the semiconductor light-emitting element in the manufacturing process according to the embodiment;

FIG. 5A is a view showing an in-process conventional semiconductor light-emitting element in a manufacturing process;

FIG. 5B is a view showing an in-process conventional semiconductor light-emitting element in the manufacturing process;

FIG. 5C is a view showing an in-process conventional semiconductor light-emitting element in the manufacturing process;

FIG. 5D is a view showing the conventional semiconductor light-emitting element in the manufacturing process;

FIG. 6 is a view showing an in-process semiconductor light-emitting element in a manufacturing process according to a different embodiment;

FIG. 7 is a view showing an in-process semiconductor light-emitting element in the manufacturing process according to the different embodiment;

FIG. 8 is a view showing an in-process semiconductor light-emitting element in the manufacturing process according to the different embodiment; and

FIG. 9 is a view showing the semiconductor light-emitting element in the manufacturing process according to the different embodiment.

### DETAILED DESCRIPTION OF THE PREFERRED EMBODIMENTS

This invention will be described in detail below on the basis of the embodiments shown in the drawings.

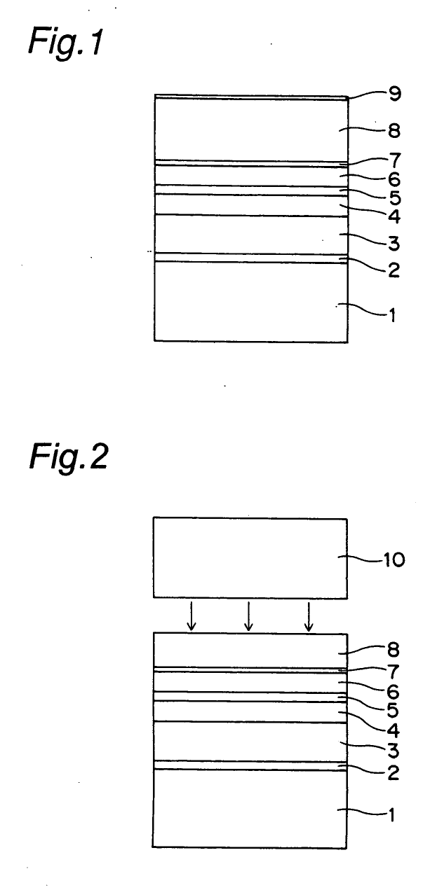

FIGS. 1 through 4 show cross sectional views of an AlGaInP based semiconductor light-emitting element in a manufacturing process thereof according to one embodiment of the present invention.

i) First of all, as shown in FIG. 1, a p-type GaAs buffer layer 2 (having a thickness of 1 μm), a p-type (Al_{0.15}Ga_{0.85})_{0.53}In_{0.47}P current diffusion layer 3 (having a thickness of 0.2 μm), a p-type Al_{0.5}In_{0.5}P cladding layer 4 (having a thickness of 0.2 μm), a p-type quantum well active layer 5 that serves as an active layer, an n-type Al_{0.5}In_{0.5}P cladding layer 6 (having a thickness of 1 μm), an n-type (Al_{0.2}Ga_{0.8})_{0.77}In_{0.23}P intermediate layer 7 (having a thickness of 0.15 μm), an n-type (Al_{0.1}Ga_{0.9})_{0.93}In_{0.07}P contact layer 8 (having a thickness of 10 μm) and an n-type GaAs cap layer 9 (having a thickness of 0.01 μm) for preventing oxidation are successively laminated in this order as semiconductor layers through epitaxial growth by the metal-organic chemical vapor deposition method (MOCVD method) on an n-type GaAs substrate 1 that serves as the first semiconductor substrate. In order to constitute a light-emitting diode, the semiconductor layers 4 and 3 grown before forming the quantum well active layer 5 are p-type, while the semiconductor layers 6, 7 and 8 grown after forming the quantum well active layer 5 are n-type (note that the buffer layer 2 and the cap layer 9 are removed in subsequent processes). In this case, Zn is used as a p-type dopant, and Si is used as an n-type dopant.

Although not shown in detail, the quantum well active layer 5 is formed by alternately laminating a plurality of barrier layers made of (Al_{0.6}Ga_{0.4})_{0.5}In_{0.5}P and a plurality of well layers made of (Al_{0.2}Ga_{0.8})_{0.5}In_{0.5}P. If the quantum well active layer 5 is made of (Al_{y}Ga_{1-y})_{z}In_{1-z}P (provided that 0≦y≦1 and 0≦z≦1), an emission wavelength of 550 nm to 670 nm is obtained. It is to be noted that the GaAs substrate 1 is opaque to the emission wavelength of 550 nm to 670 nm of this quantum well active layer 5.

ii) Next, as shown in FIG. 2, the surface (upper surface in FIG. 2) of the epitaxial growth layer is polished to be flattened, and thereafter, the exposed surface of the contact layer 8 is subjected to surface processing with an etchant to remove oxide. On the other hand, there is prepared an n-type GaP substrate 10 that serves as the second semiconductor substrate transparent to the emission wavelength of 550 nm to 670 nm of the quantum well active layer 5, and the surface of this GaP substrate 10 is similarly subjected to surface processing with an etchant to remove oxide.

Subsequently, both of them are sufficiently cleaned and dried. Thereafter, the surface of the contact layer 8 located on the GaAs substrate 1 and the surface of the GaP substrate 10 closely adhere to each other under the pressurized state, and heat treatment is carried out at a temperature of 750 to 800° C. for one hour in a vacuum or in hydrogen or nitrogen purging. Thereby, the two substrates are directly connected to each other.

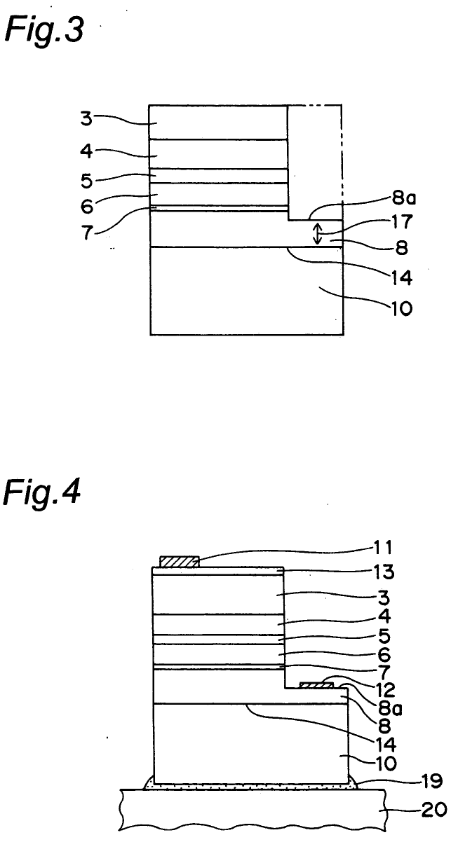

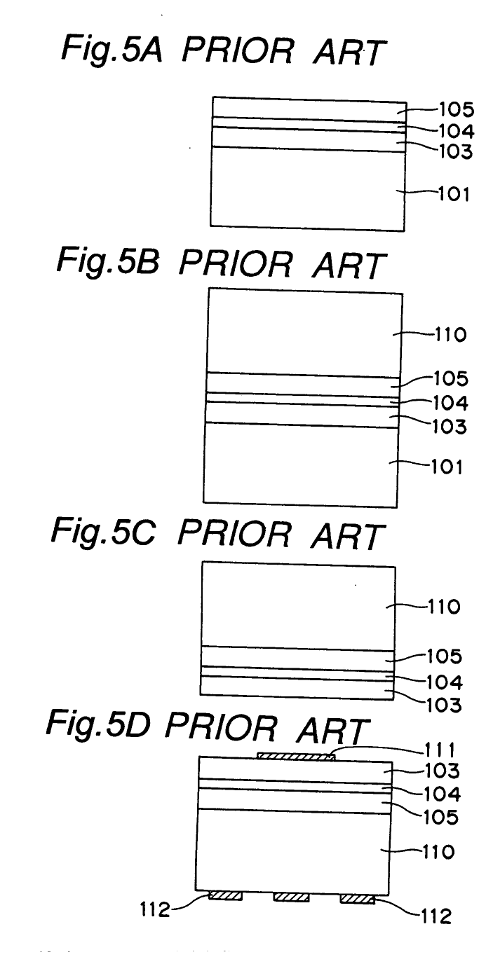

iii) Next, as shown in FIG. 3, the n-type GaAs substrate 1 and the p-type GaAs buffer layer 2 are removed by etching with an etchant containing a mixed liquor of ammonia and a hydrogen peroxide aqueous solution. It is to be noted that FIG. 3 is illustrated upside down with respect to FIGS. 1 and 2.

iv) Next, a partial region (region indicated by the two-dot chain lines in the figure) of the semiconductor layers 3, 4, 5, 6, 7 and 8 is removed by etching from the surface side (side opposite from the GaP substrate 10) of the semiconductor layer 3 with use of an etchant containing hydrochloric acid, acetic acid and hydrogen peroxide aqueous solution or containing sulfuric acid, phosphoric acid, hydrogen peroxide aqueous solution and pure water. Thereby, a step 8a is formed in the contact layer 8, where the step 8a is located at the in-depth position beyond the quantum well active layer 5.

In this case, a thickness (this is referred to as the “remainder thickness”) between the step 8a and a direct connection interface 14 of the contact layer 8 with respect to the GaP substrate 10 should preferably be set not smaller than 1 μm and not greater than 4 μm. In the case that the remainder thickness is not greater than 4 82 m, the step 8a can stably be set at the in-depth position beyond the position of the quantum well active layer 5. In the case that the remainder thickness is not smaller than 1 μm, continuity between a second electrode described later and the contact layer 8 is stably secured.

v) Next, as shown in FIG. 4, a translucent electrode layer 13 made of ITO (tin doped indium oxide), GZO (gallium doped zinc oxide) or the like, which is transparent to the emission wavelength of 550 nm to 670 nm of the quantum well active layer 5, is formed as the first electrode on the entire surface region of the current diffusion layer 3, where the portion of the current diffusion layer 3 located above the step 8a is cut out. A first bonding pad 11, which is constructed of a laminate of AuZn, Mo and Au, is formed on a portion of the translucent electrode layer 13.

Subsequently, a second bonding pad 12 made of AuSi is formed as the second electrode on the step 8a of the contact layer 8 (fabrication of the element is completed).

vi) Subsequently, for application to a semiconductor device, the semiconductor light-emitting element (i.e., chip) is bonded onto a heat sink 20 using a well-known thermally conductive adhesive 19 that has a principal ingredient of, for example, silicone resin with the GaP substrate 10 on the lower side. Moreover, metal wires are connected to the first bonding pad 11 and the second bonding pad 12 by wire bonding.

During the operation of the semiconductor light-emitting element, an electric power is applied across the first bonding pad 11 and the second bonding pad 12. As a result, electrification is conducted from the first bonding pad 11 to the second bonding pad 12 through the translucent electrode layer 13, the current diffusion layer 3, the cladding layer 4, the quantum well active layer 5, the cladding layer 6, the intermediate layer 7 and the contact layer 8. Thereby, the quantum well active layer 5 emits light of the emission wavelength of 550 nm to 670 nm.

This semiconductor light-emitting element is provided with the GaP substrate 10 transparent to the emission wavelength of 550 nm to 670 nm. Therefore, the semiconductor light-emitting element is able to produce light not only from the upper surface of the chip but also from the four side surfaces and to emit reflected light on the lower surface from the upper surface and the side surfaces, so that the external emission efficiency can be improved. Furthermore, the translucent electrode layer 13 is transparent to the emission wavelength of 550 nm to 670 nm, and therefore, the light emission to the upper surface of the chip is not disturbed by the translucent electrode layer 13. Therefore, the external emission efficiency can be further improved. Moreover, during operation, electrification current is diffused by this translucent electrode layer 13, and the current is uniformly injected into the quantum well active layer 5. Therefore, the internal quantum efficiency is improved. As the results, the characteristics of the semiconductor light-emitting element are improved, and high luminance is achieved.

Moreover, the electrification is effected between the first bonding pad 11 and the second bonding pad 12, in other words, between the translucent electrode 13 and the contact layer 8. Thus, no current substantially flows through the direct connection interface 14. Therefore, the electrical characteristics are scarcely influenced by the state of the direct connection interface 14. Therefore, even when an incomplete junction attributed to the hillock or the like is generated in the direct connection interface 14, satisfactory electrical characteristics can be exhibited, and a high yield is obtained.

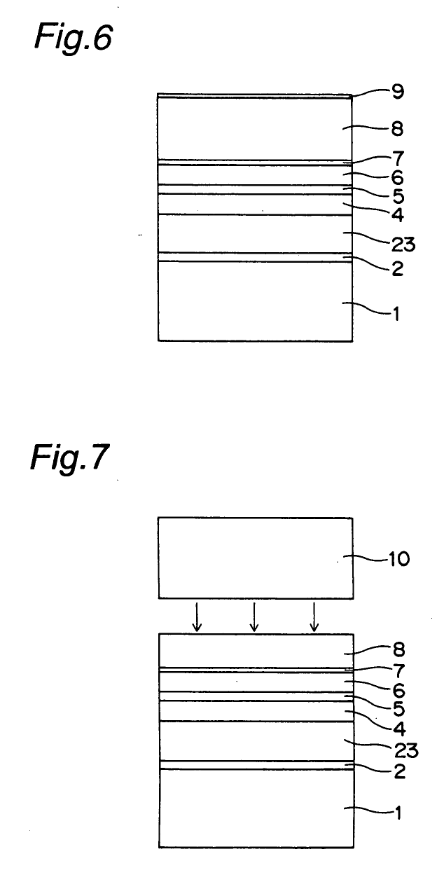

FIGS. 6 through 9 show the cross sections of the AlGaInP based semiconductor light-emitting element of another embodiment in the manufacturing process thereof.

First of all, as shown in FIG. 6, a p-type GaAs buffer layer 2 (having a thickness of 1 μm), a p-type Al_{0.5}Ga_{0.5}As current diffusion layer 23 (having a thickness of 5 μm), a p-type Al_{0.5}In_{0.5}P cladding layer 4 (having a thickness of 1 μm), a p-type quantum well active layer 5 that serves as an active layer, an n-type Al_{0.5}In_{0.5}P cladding layer 6 (having a thickness of 1 μm), an n-type (Al_{0.2}Ga_{0.8})_{0.77}In_{0.23}P intermediate layer 7 (having a thickness of 0.15 μm), an n-type (Al_{0.1}Ga_{0.9})_{0.93}In_{0.07}P contact layer 8 (having a thickness of 10 μm) and an n-type GaAs cap layer 9 (having a thickness of 0.01 μm) for preventing oxidation are successively laminated in this order as semiconductor layers through epitaxial growth by the metal-organic chemical vapor deposition method (MOCVD method) on an n-type GaAs substrate 1 that serves as the first semiconductor substrate. In order to constitute a light-emitting diode, the semiconductor layers 4 and 23 grown before forming the quantum well active layer 5 are p-type, while the semiconductor layers 6, 7 and 8 grown after forming the quantum well active layer 5 are n-type (note that the buffer layer 2 and the cap layer 9 are removed in subsequent processes). In this case, Zn is used as a p-type dopant, and Si is used as an n-type dopant.

It is desirable that the p-type Al0.5Ga0.5As current diffusion layer 23 has a layer thickness of not smaller than 5 μm in order to obtain sufficient current diffusion and has a layer thickness of not greater than 10 μm in carrying out the etching and other processes.

Although not shown in detail, the quantum well active layer 5 is formed by alternately laminating a plurality of barrier layers made of (Al_{0.6}Ga_{0.4})_{0.5}In_{0.5}P and a plurality of well layers made of (Al_{0.2}Ga_{0.8})_{0.5}In_{0.5}P. If the quantum well active layer 5 is made of (Al_{y}Ga_{1-y}y)_{z}In_{1-z}P (provided that 0≦y≦1 and 0≦z≦1), an emission wavelength of 550 nm to 670 nm is obtained. It is to be noted that the GaAs substrate 1 is opaque to the emission wavelength of 550 nm to 670 nm of this quantum well active layer 5.

Next, as shown in FIG. 7, the surface (upper surface in FIG. 6) of the epitaxial growth layer is polished to be flattened, and thereafter, the exposed surface of the contact layer 8 is subjected to surface processing with an etchant to remove oxide. On the other hand, there is prepared an n-type GaP substrate 10 that serves as the second semiconductor substrate transparent to the emission wavelength of 550 nm to 670 nm of the quantum well active layer 5, and the surface of this GaP substrate 10 is similarly subjected to surface processing with an etchant to remove oxide.

Subsequently, both of them are sufficiently cleaned and dried. Thereafter, the surface of the contact layer 8 located on the GaAs substrate 1 and the surface of the GaP substrate 10 closely adhere to each other under the pressurized state, and heat treatment is carried out at a temperature of 750 to 800° C. for one hour in a vacuum or in hydrogen or nitrogen purging. Thereby, the two substrates are directly connected to each other.

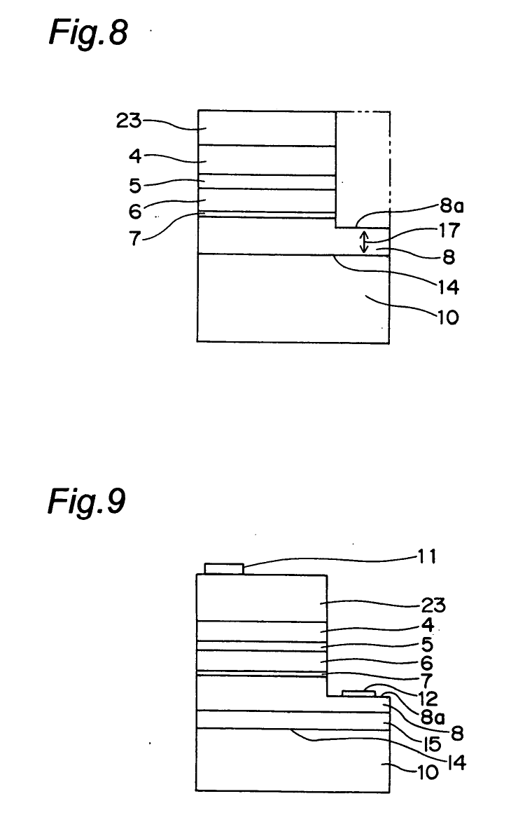

Next, as shown in FIG. 8, the n-type GaAs substrate 1 and the p-type GaAs buffer layer 2 are removed by etching with an etchant containing a mixed liquor of ammonia and a hydrogen peroxide aqueous solution. It is to be noted that FIG. 8 is illustrated upside down with respect to FIGS. 6 and 7.

Next, a partial region (region indicated by the two-dot chain lines in the figure) of the semiconductor layers 23, 4, 5, 6, 7 and 8 is removed by etching from the surface side (side opposite from the GaP substrate 10) of the semiconductor layer 3 using an etchant of containing sulfuric acid, hydrogen peroxide aqueous solution and pure water or containing sulfuric acid, phosphoric acid, hydrogen peroxide aqueous solution and pure water. Thereby, a step 8a is formed in the contact layer 8, where the step 8a is located at in-depth the position beyond the quantum well active layer 5.

In this case, a thickness (this is referred to as the “remainder thickness”) between the step 8a and a direct connection interface 14 of the contact layer 8 with respect to the GaP substrate 10 should preferably be set not smaller than 1 μm and not greater than 4 μm. In the case that the remainder thickness is not greater than 4 μm, the step 8a can stably be set at the in-depth position beyond the quantum well active layer 5. In the case that the remainder thickness is not smaller than 1 μm, continuity between a second electrode described later and the contact layer 8 is stably secured.

Next, as shown in FIG. 9, a first bonding pad 11, which is constructed of a laminate of AuZn, Mo and Au, is formed on the upward partial region.

Subsequently, a second bonding pad 12 made of AuSi is formed as the second electrode on step 8a in the contact layer 8 (fabrication of the element is completed).

Subsequently, for application to a semiconductor device, the semiconductor light-emitting element (i.e., chip) is bonded onto a heat sink 20 using the well-known thermally conductive adhesive 19 that has a principal ingredient of, for example, silicone resin with the GaP substrate 10 located on the lower side (see FIG. 4). Moreover, metal wires are connected to the first bonding pad 11 and the second bonding pad 12 by wire bonding.

During the operation of the semiconductor light-emitting element, an electric power is applied across the first bonding pad 11 and the second bonding pad 12. As a result, electrification is conducted from the first bonding pad 11 to the second bonding pad 12 through the current diffusion layer 23, the cladding layer 4, the quantum well active layer 5, the cladding layer 6, the intermediate layer 7 and the contact layer 8. Thereby, the quantum well active layer 5 emits light of the emission wavelength of 550 nm to 670 nm.

This semiconductor light-emitting element is provided with the GaP substrate 10 transparent to the emission wavelength of 550 nm to 670 nm. Therefore, the semiconductor light-emitting element is able to produce light not only from the upper surface of the chip but also from the four side surfaces and to emit reflected light on the lower surface from the upper surface and the side surfaces, so that the external emission efficiency can be improved. Furthermore, current is diffused by the current diffusion layer 23, and the current is uniformly injected into the quantum well active layer 5. Therefore, the internal quantum efficiency is improved. As the results, the characteristics of the semiconductor light-emitting element are improved, and high luminance is achieved.

The semiconductor laminate of the semiconductor light-emitting element may constitute the surface of the semiconductor laminate while being located between the active layer and the first electrode and include a current diffusion layer made of AlₓGa₁₋ₓAs (0≦x≦1)

In the semiconductor device where the aforementioned semiconductor light-emitting element is provided on the heat sink 20, the heat sink 20 does not become an electrification path for the semiconductor light-emitting element and is only required to have the functions of heat radiation and mounting. Therefore, the material of the heat sink 20 may be a metal or an insulator. This allows variation of the adoptable package to be widened. The heat sink 20 is preferably made of a material having a comparatively high thermal conductivity such as aluminum nitride (AlN) in order to improve the temperature characteristic.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

1. A semiconductor light-emitting element comprising:
a semiconductor laminate including an active layer that emits light of a prescribed emission wavelength; and
a substrate that is transparent to the emission wavelength and directly connected to the semiconductor laminate, wherein
a step is formed in the semiconductor laminate, the step being located at an in-depth position beyond the active layer from a surface of the semiconductor laminate opposite to a direct connection interface between the semiconductor laminate and the substrate, and
a first electrode and a second electrode are provided on the surface and the step of the semiconductor laminate, respectively.

2. The semiconductor light-emitting element as claimed in claim 1, wherein
the first electrode has a translucent electrode layer that is transparent to the emission wavelength and provided entirely on the surface of the semiconductor laminate, excluding the step.

3. The semiconductor light-emitting element as claimed in claim 1, wherein
the semiconductor laminate and the substrate are electrically separated from each other by a constituent that constitutes a p-n junction.

4. The semiconductor light-emitting element as claimed in claim 3, wherein the constituent that constitutes the p-n junction is comprised of the n-type substrate and a p-type semiconductor layer deposited on the substrate.

5. The semiconductor light-emitting element as claimed in claim 3, wherein
the constituent that constitutes the p-n junction is comprised of the n-type substrate and a p-type diffusion layer formed by impurity diffusion on a surface of the substrate.

6. The semiconductor light-emitting element as claimed in claim 1, wherein
a thickness between the step of the semiconductor laminate and the direct connection interface is not smaller than 1 μm and not greater than 4 μm.

7. The semiconductor light-emitting element as claimed in claim 1, wherein
the semiconductor laminate includes a current diffusion layer that is located between the active layer and the first electrode and has the surface of the semiconductor laminate.

8. The semiconductor light-emitting element as claimed in claim 7, wherein
the current diffusion layer is comprised of (Al_{y}Ga_{1-y})_{z}In_{1-z}P (0≦y≦1, 0≦z≦1).

9. The semiconductor light-emitting element as claimed in claim 7, wherein
a thickness of the current diffusion layer is not smaller than 0.2 μm and not greater than 10 μm.

10. A semiconductor device having a semiconductor light-emitting element comprising:
a semiconductor laminate including an active layer that emits light of a prescribed emission wavelength; and
a substrate that is transparent to the emission wavelength and directly connected to the semiconductor laminate, wherein
a step is formed in the semiconductor laminate, the step being located at an in-depth position beyond the active layer from a surface of the semiconductor laminate opposite to a direct connection interface between the semiconductor laminate and the substrate,
a first electrode and a second electrode are provided on the surface and the step of the semiconductor laminate, respectively, and
a surface of the substrate surface located opposite to the direct connection interface is bonded to an electrically insulating heat sink.

11. The semiconductor device as claimed in claim 10, wherein
the electrically insulating heat sink is made of aluminum nitride.

12. A semiconductor light-emitting element manufacturing method comprising:
growing a semiconductor laminate including an active layer that emits light of a prescribed emission wavelength on a first semiconductor substrate;
directly connecting a second semiconductor substrate transparent to the emission wavelength of the active layer to a surface of the semiconductor laminate opposite to another surface of the semiconductor laminate contacting the first semiconductor substrate;
removing the first semiconductor substrate;
forming a step in the semiconductor laminate by etching such that the step is located at an in-depth position beyond the active layer from a surface of the semiconductor laminate opposite to a direct connection interface between the semiconductor laminate and the second substrate; and
providing a first electrode and a second electrode on the surface and the step of the semiconductor laminate, respectively.
